(19) United States
(12) Patent Application Publication
(10) Pub. No.: US 2023/0103023 A1
(43) Pub. Date: Mar. 30, 2023

(54) Semiconductor Die, Semiconductor Device and Method for Forming a Semiconductor Die

(71) Applicant: Intel Corporation, Santa Clara, CA (US)

(72) Inventors: Thomas WAGNER, Regelsbach (DE); Martin OSTERMAYR, Woerth (DE); Joachim SINGER, Neubiberg (DE); Klaus HEROLD, Munich (DE)

(21) Appl. No.: 17/448,716

(22) Filed: Sep. 24, 2021

(51) Int. Cl. H01L 23/498; H01L 23/48; H01L 21/48; H01L 23/00

(52) U.S. Cl. CPC H01L 23/49822; H01L 23/481; H01L 23/49838; H01L 21/4857; H01L 21/486; H01L 24/80; H01L 2224/80001

(57) ABSTRACT

A semiconductor die is provided. The semiconductor die comprises a plurality of transistors arranged at a front side of a semiconductor substrate and an electrically conductive structure. A top surface of the electrically conductive structure is contacted at the front side of the semiconductor substrate and a bottom surface of the electrically conductive structure is contacted at a backside of the semiconductor substrate. Further, the semiconductor die comprises a backside metallization layer stack attached to the backside of the semiconductor substrate. A first portion of a wiring structure is formed in a first metallization layer of the backside metallization layer stack and a second portion of the wiring structure is formed in a second metallization layer of the backside metallization layer stack. Further, a tapered vertical connection is formed between the first portion of the wiring structure and the second portion of the wiring structure, wherein the first metallization layer is closer to the semiconductor substrate than the second metallization layer. A width of the tapered vertical connection increases towards the first metallization layer.

### FIELD

The present disclosure relates to the field of semiconductor devices. In particular, examples relate to a semiconductor die, a semiconductor device and a method for forming a semiconductor die.

### BACKGROUND

The shrinkage of advanced semiconductor technologies is mandatory to create silicon dies with new and improved functionality. This shrinkage is limited by an input/output (I/O) of signals and/or a power functionality of a silicon die due to the footprint of elements (e.g., of vias). For example, a connection via a back-end-of-line (BEOL) stack may be long and on high power and at high switching rates challenging to realize. Further, the connection may be limited by a rate of change of current that the connection can provide without drops or spikes in the current to cause fails in the functionality. Via sizes, copper thickness and path lengths are limiting factors of the BEOL stack. Thus, there may be a need for an improved concept for providing power to the silicon die.

### BRIEF DESCRIPTION OF THE FIGURES

Some examples of apparatuses and/or methods will be described in the following by way of example only, and with reference to the accompanying figures, in which

FIG. 1 shows a cross-sectional view of a semiconductor die;

FIG. 2 shows a cross-sectional view of another example of a semiconductor die;

FIG. 3 shows an example of a method for forming a semiconductor die;

FIGS. 4a to 4j show an example of a method for forming a semiconductor die;

FIG. 5 shows a cross-sectional view of a semiconductor device; and

FIG. 6 illustrates a computing device.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of the group A and B”. The same applies for combinations of more than 2 Elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof

Unless otherwise defined, all terms (including technical and scientific terms) are used herein in their ordinary meaning of the art to which the examples belong.

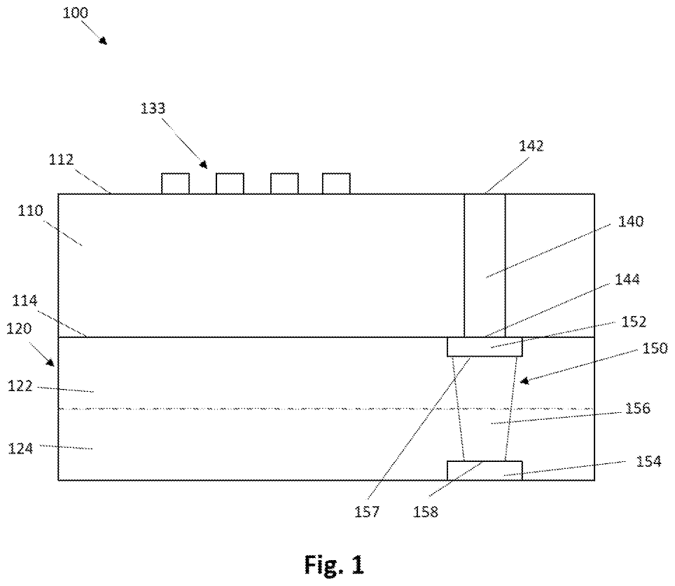

FIG. 1 shows a cross-sectional view of a semiconductor die 100. The semiconductor die 100 comprises a plurality of transistors 133 arranged at a front side of a semiconductor substrate 112 and an electrically conductive structure 140. A top surface of the electrically conductive structure 142 is contacted at the front side of the semiconductor substrate 112 and a bottom surface of the electrically conductive structure 144 is contacted at a backside of the semiconductor substrate 114. Further, the semiconductor die 100 comprises a backside metallization layer stack 120 attached to the backside of the semiconductor substrate 114. A first portion of a wiring structure 152 of the backside metallization layer stack is formed in a first metallization layer 122 of the backside metallization layer stack 120 and a second portion of the wiring structure 154 is formed in a second metallization layer 124 of the backside metallization layer stack 120. Further, a tapered vertical connection 156 is formed between the first portion of the wiring structure 152 and the second portion of the wiring structure 154. The first metallization layer 122 is closer to the semiconductor substrate 110 than the second metallization layer 124. A width of the tapered vertical connection 156 increases towards the first metallization layer 122.

By attaching the backside metallization layer stack 120 to the semiconductor substrate 110 an improved electrical connection for the plurality of transistors 133 can be provided and/or a manufacturing process can be eased. For example, attaching the backside metallization layer stack 120 may avoid the forming of trough substrate vias (TSV) or nano TSVs to electrically connect or power the plurality of transistors 133. Thus, a tradeoff between the connection of the plurality of transistors 133 and a structure density for thick silicon substrate (which enable an improved warpage and easier handling in the manufacturing) may be omitted. For example, also the generation of nano TSVs, which requires very thin wafer handling, which is a complex process with risk for higher yield loss, as it is challenging to hit the electrically conductive line 140 of the semiconductor substrate 110 on each dimension from the backside of the silicon substrate 114, can be omitted by attaching the backside metallization layer stack 120 to the semiconductor substrate 110.

The backside metallization layer stack 120 can be manufactured/processed separately from the semiconductor substrate 110. Thus, all processes to generate the backside metallization layer stack 120 may be done on an, e.g., optimized front-end-of-line (FEOL) process and/or independent of the functional process node. For example, a contact interface structure to connect the backside metallization layer stack 120 to the electrically conductive line 140 of the semiconductor substrate 110 can be formed. Since, the contact interface structure is formed separately of the semiconductor substrate manufacturing process an overall assembly yield may be improved, by scrap low yielding backside metallization layer stacks 120 (e.g., formed on a wafer) before attaching them to a semiconductor substrate 110, compared to a TSVs process on the semiconductor substrate 110, where every TSV defect result in direct yield loss. Thus, by manufacturing/processing the backside metallization layer stack 120 separately from the semiconductor substrate 110 a yield of the semiconductor device manufacturing can be increased.

Further, additional materials to improve the functionality of the semiconductor device 100 can be implemented into the backside metallization layer stack 120 (e.g. special dielectric for caps or magnetic material for coils) without influencing the (functional) semiconductor substrate 110. This way, the backside metallization layer stack 120 can be adjusted to a use case without limitation due to a lack of process capability of the semiconductor substrate 110.

The electrically conductive structure 140 may be an electrically conductive line 140 or may comprise an electrically conductive line 140. The electrically conductive line 140 may run laterally in a trench, which extends vertically into the semiconductor substrate 110. The top surface of the electrically conductive line 140 may be coplanar with the front side surface of the semiconductor substrate 110 or may protrude from the front side surface of the semiconductor substrate 110. The top surface of the electrically conductive line 140 may be contacted by one or more vias and/or one or more contact structures one or more transistors. The electrically conductive line 140 may extend to the back side of the semiconductor substrate 110 (if the semiconductor substrate is thin). In this case, the bottom surface of the electrically conductive structure 140 may be the bottom surface of the electrically conductive line 140. In this way, a connection from front side to back side may be implemented with low effort, since the number of necessary process steps may be kept low. Alternatively, a through substrate via may be connected to the electrically conductive line (e.g. if the semiconductor substrate is thick). For example, the through substrate via may extend from a bottom surface of the electrically conductive line 140 to the backside of the semiconductor substrate. In this case, the bottom surface of the electrically conductive structure 140 may be the bottom surface of the through substrate via.

The electrically conductive line 140 may be formed of any appropriate conductive material, such as copper, silver, nickel, gold, aluminum, other metals or alloys, or combinations of materials, for example. The electrically conductive line 140 may be an electrically conductive trace.

The wiring structure 150 may be formed of any appropriate conductive material, such as copper, silver, nickel, gold, aluminum, other metals or alloys, or combinations of materials, for example.

Although FIG. 1 (and others of the accompanying drawings) illustrate a specific number and arrangement of the electrically conductive line 140 in the semiconductor substrate 110 and of the wiring structure 150 in the backside metallization layer stack 120 these are simply illustrative, and any suitable number and arrangement may be used.

In some embodiments, the electrically conductive line 140 and/or the wiring structure 150 may comprises a pillar of conductive material (e.g., a metal, such as copper), a through-hole plated with a conductive material, a via filled with a conductive material, a vertical or planer trace, a wire, a contact structure, a wiring structure or any other conductive trace along which electrical signals are to flow, e.g., the first portion or the second portion to contact the electrically conductive line 140 at the front side 112 and/or and the backside of the semiconductor substrate 114, respectively. Other conductive elements may be disposed between or around multiple different vias in an electrically conductive line 140/wiring structure 150. For example, the wiring structure 150 may comprise wiring traces in the at least one the first 122 or second metallization layer 124. For example, the wiring structure 150 may comprise vias in an interlayer dielectric (ILD) layer.

As can be seen in FIG. 1 the wiring structure 150 comprises a tapered vertical connection 156, e.g., a tapered via. The thickness of the tapered vertical connection 156 is at a first end 157 larger as at an opposing second end 158. The first end 157 is closer to the backside of the semiconductor substrate 114 as the second end 158. For example, the tapered vertical connection 156 has a tapered cross-sectional configuration, where the tapered vertical connection walls taper so as to form a reduced cross-sectional dimension in a direction from the first metallization layer 122 toward the second metallization layer 124.

The tapered vertical connection 156 may be directly electrically connected with the first portion 152 and/or the second portion of the wiring structure 154.

The semiconductor substrate 110 may comprise any type of substrate. For example, the semiconductor substrate 110 may comprise or may be composed of a single crystal of a material which may include, but is not limited to, silicon, germanium, silicon-germanium, germanium-tin, silicon-germanium-tin, or a group III-V compound semiconductor material. The semiconductor substrate 110 may be a bulk substrate or may be part of a semiconductor-on-insulator SOI substrate.

The backside metallization layer stack 120 may be attached to the backside of the semiconductor substrate 114 by a direct bonding (DB) process, e.g., a front side of the backside metallization layer stack (and the backside of the semiconductor substrate 114) may comprise a DB region. For example, a (hybrid) bond pad may be formed on a front side of the backside metallization layer stack, e.g., the first portion 152 may be the (hybrid) bond pad. As described above the first portion 152 (e.g., the (hybrid) pond pad) can be formed separately from the semiconductor substrate 110 processing, thus an alignment on a thick, good processable substrate (e.g., a wafer) upfront on the exact location where they are needed, e.g., to contact the electrically conductive line 140 at the backside of the semiconductor substrate 114, can be achieved.

As used herein, the term “direct bonding” is used to include metal-to-metal bonding techniques (e.g., copper-to-copper bonding, or other techniques in which the DB contacts of opposing DB interfaces are brought into contact first, then subject to heat and compression) and hybrid bonding techniques (e.g., techniques in which the DB dielectric of opposing DB interfaces are brought into contact first, then subject to heat and sometimes compression, or techniques in which the DB contacts and the DB dielectric of opposing DB interfaces are brought into contact substantially simultaneously, then subject to heat and compression). In such techniques, the DB contacts and the DB dielectric at one DB interface are brought into contact with the DB contacts and the DB dielectric at another DB interface, respectively, and elevated pressures and/or temperatures may be applied to cause the contacting DB contacts and/or the contacting DB dielectrics to bond. In some embodiments, this bond may be achieved without the use of intervening solder or an anisotropic conductive material, while in some other embodiments, a thin cap of solder may be used in a DB interconnect to accommodate planarity, and this solder may become an intermetallic compound (IMC) in the DB region during processing. In some embodiments, this bond may be achieved by use of copper-copper bonding. DB interconnects may be capable of reliably conducting a higher current than other types of interconnects; for example, some conventional solder interconnects may form large volumes of brittle IMCs when current flows, and the maximum current provided through such interconnects may be constrained to mitigate mechanical failure.

A DB dielectric may include one or more dielectric materials, such as one or more inorganic dielectric materials. For example, a DB dielectric may include silicon and nitrogen (e.g., in the form of silicon nitride); silicon and oxygen (e.g., in the form of silicon oxide); silicon, carbon, and nitrogen (e.g., in the form of silicon carbonitride); carbon and oxygen (e.g., in the form of a carbon-doped oxide); silicon, oxygen, and nitrogen (e.g., in the form of silicon oxynitride); aluminum and oxygen (e.g., in the form of aluminum oxide); titanium and oxygen (e.g., in the form of titanium oxide); hafnium and oxygen (e.g., in the form of hafnium oxide); silicon, oxygen, carbon, and hydrogen (e.g., in the form of tetraethyl orthosilicate (TEOS)); zirconium and oxygen (e.g., in the form of zirconium oxide); niobium and oxygen (e.g., in the form of niobium oxide); tantalum and oxygen (e.g., in the form of tantalum oxide); and combinations thereof.

A DB contact may include a pillar, a pad, or other structure. The DB contacts may have a same structure at both DB interfaces (a front side of the backside metallization layer stack and the backside of the semiconductor substrate 114), or the DB contacts at different DB interfaces may have different structures. For example, in some embodiments, a DB contact in one DB interface may include a metal pillar (e.g., a copper pillar), and a complementary DB contact in a complementary DB interface may include a metal pad (e.g., a copper pad) recessed in a dielectric. A DB contact may include any one or more conductive materials, such as copper, manganese, titanium, gold, silver, palladium, nickel, copper and aluminum (e.g., in the form of a copper aluminum alloy), tantalum (e.g., tantalum metal, or tantalum and nitrogen in the form of tantalum nitride), cobalt, cobalt and iron (e.g., in the form of a cobalt iron alloy), or any alloys of any of the foregoing (e.g., copper, manganese, and nickel in the form of manganin). In some embodiments, the DB dielectric and the DB contacts of a DB interface may be manufactured using low-temperature deposition techniques (e.g., techniques in which deposition occurs at temperatures below degrees Celsius, or below degrees Celsius), such as low-temperature plasma-enhanced chemical vapor deposition (PECVD).

The semiconductor die 100 may take any suitable form. For example, the semiconductor die 100 may be a processor die (e.g. CPU, GPU or DSP), a memory die, a sensor die, or a platform controller hub, or may include any combination of circuits having these functions.

In an example, the first portion of the wiring structure 152 may be a contact interface structure connected to the bottom surface of the electrically conductive line. For example, the contact interface structure may be a (hybrid) bond pad. Thus, the electrically line 140, e.g., the bottom surface of the electrically conductive line 144, may be electrically connected to the contact interface structure.

In an example, the backside metallization layer stack 120 may further comprise a bonding surface layer arranged besides the contact interface structure comprising at least one of silicon carbon nitride, silicon oxide or polyimide. The bonding surface layer and the hybrid bonding pads may be utilized to perform a hybrid bonding process. Hybrid bonding is a technique to bond metal-electrode and insulator interfaces, such as Cu/SiO₂ hybrid surface (e.g., the first portion of the wiring structure 152 and the bonding layer).

In an example, a length of the contact interface structure may be at most 160 nm, or at most 130 nm or at most 100 nm and/or at least 30 nm or at least 60 nm or at least 80 nm. In an example, a minimal lateral dimension of the bottom surface of the electrically conductive line 144 may be at most 160 nm, or at most 130 nm or at most 100 nm and/or at least 30 nm or at least 60 nm or at least 80 nm.

In an example, a thickness of the first metallization layer 122 may be at most 200 nm, or at most 150 nm, at most 100 nm, at most 80 nm, at most 60 nm or at most 40 nm and/or at least 40 nm or at least 60 nm or at least 80 nm. In an example, a thickness of the semiconductor substrate 110 may be at most 300 nm, or at most 200 nm, at most 100 nm, at most 80 nm, at most 50 nm or at most 20 nm and/or at least 20 nm or at least 50 nm or at least 80 nm.

In an example, the plurality of transistors 133 may comprise at least one of a fin field-effect transistor, a nanowire transistor, a ribbon transistor or a gate all around transistor. A gate all around transistor is a structure where the gate contacts the channel from all sides.

In an example, the electrically conductive line 140 may be electrically insulated from the semiconductor substrate 110.

In an example, a layer (e.g., the first metallization layer 122 or the second metallization layer 124) of the backside metallization layer stack 120 may comprise a dielectric material of a capacitor, e.g., silicon oxide, silicon nitride, etc. In an example, a layer (e.g., the first metallization layer 122 or the second metallization layer 124) of the backside metallization layer stack 120 may comprise a magnetic material of an inductor, e.g., iron oxide, iron platinum, etc. In an example, a layer (e.g., the first metallization layer 122 or the second metallization layer 124) of the backside metallization layer stack 120 may comprise a material with a thermal conductivity of at least 1 W/mK, at least 2 W/mK or at least 3 W/mK.

In an example, the backside metallization layer stack 120 may further comprise a circuit element (e.g., a capacitor, resistor, inductor, etc.) electrically connected to the electrically conductive line 140. Thus, an integration of the circuit element can be eased by integrating a necessary circuit element into the backside metallization layer stack 120 instead of into the semiconductor substrate 110.

In an example, the semiconductor die 100 may further comprise circuitry comprising at least one transistor of the plurality of transistors. The circuit element is electrically connected to the transistor of the circuitry via the electrically conductive line 140. Thus, a circuitry can be provided in an eased way utilizing the electrically conductive line 140.

In an example, the semiconductor die 100 may further comprise a front side wiring layer stack formed on the front side of the semiconductor substrate 112. The front side wiring layer stack comprises a front side wiring structure electrically connected to the wiring structure of the backside metallization layer stack. For example, the front side wiring layer stack may be formed with FEOL and/or BEOL process(es).

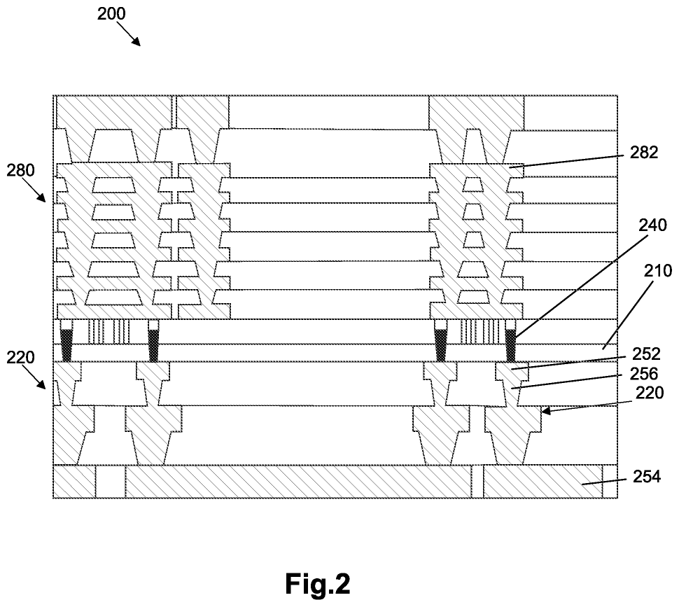

More details and aspects are mentioned in connection with the examples described below. The example shown in FIG. 1 may comprise one or more optional additional features corresponding to one or more aspects mentioned in connection with the proposed concept or one or more examples described below (e.g., FIGS. 2-6).

FIG. 2 shows a cross-sectional view of another example of a semiconductor die 200. The semiconductor die 200 comprises a semiconductor substrate 210 and a backside metallization layer stack 220. The backside metallization layer stack 220 comprises a wiring structure 250, which comprises a first portion of the wiring structure 252, e.g., a hybrid bond pad 252, a tapered vertical connection 256 and a second portion of the wiring structure 254. The second portion of the wiring structure 254 may be a contact interface structure, e.g., to electrically contact the backside metallization layer stack 220 to, e.g., a redistribution layer, a package substrate, a lead frame, etc.

Further, the semiconductor die 200 comprises a front side wiring layer stack 280, which comprises a front wiring structure 282, e.g., to electrically connect the plurality of transistors to an external electrical signal (e.g., a power supply). The front side wiring layer stack 280 may be attached to the front side of the semiconductor substrate 210. The front wiring structure 282 may be electrically connected to the wiring structure 250.

For example, the electrically conductive line 240 of the semiconductor substrate 210 may be electrically connected via a bottom surface of the electrically conductive line 244 with the hybrid bond pad 252 and the front wiring structure 282 may be electrically connected with a front surface of the electrically conductive line 242 with the front wiring structure 282, e.g., via a contact interface structure (e.g., a bond pad).

For example, the second portion of the wiring structure 254 may act as a backside metallization, e.g., the second portion of the wiring structure 254 may be uncovered.

By attaching the backside metallization layer stack 220 to the semiconductor substrate 210 both can be manufactured/processed separately, as described above. For example, the front side wiring layer stack 280 may be formed by FEOL and/or BEOL process(es) excluding dielectric material and the backside metallization layer stack 220 may be formed by FEOL and/or BEOL process(es) including dielectric material and also the forming of a backside metallization.

The attaching may be performed by a hybrid bonding process utilizing the hybrid bond pad 252. The hybrid bond pad 252 may be directly bonded to the bottom surface of the electrically conductive line 244 via hybrid bonding. This way, an interconnect for an electrical signal, e.g., a power supply, a V_{SS}, etc. may be formed in an improved way from the backside of the semiconductor die 200 to the electrically conductive line 240 via the wiring structure 250.

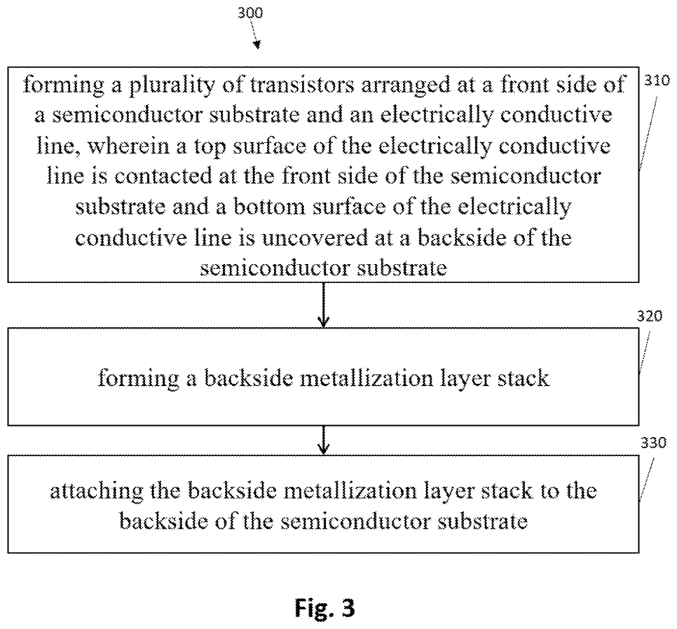

More details and aspects are mentioned in connection with the examples described above and/or below. The example shown in FIG. 2 may comprise one or more optional additional features corresponding to one or more aspects mentioned in connection with the proposed concept or one or more examples describe above (e.g., FIG. 1) and/or below (e.g., FIGS. 3-6).

FIG. 3 shows an example of a method 300 for forming a semiconductor die. The method 300 comprises forming 310 a plurality of transistors arranged at a front side of a semiconductor substrate and an electrically conductive structure. A top surface of the electrically conductive structure is contacted at the front side of the semiconductor substrate and a bottom surface of the electrically conductive structure is uncovered at a backside of the semiconductor substrate. Further, the method 300 comprises forming 320 a backside metallization layer stack and attaching 330 the backside metallization layer stack to the backside of the semiconductor substrate.

The electrically conductive structure may be an electrically conductive line or may comprise an electrically conductive line. The electrically conductive line may run laterally in a trench, which extends vertically into semiconductor substrate. The top surface of the electrically conductive line may be coplanar with the front side surface of the semiconductor substrate or may protrude from the front side surface of the semiconductor substrate. The top surface of the electrically conductive line may be contacted by one or more vias and/or one or more contact structures one or more transistors. The electrically conductive line may extend to the back side of the semiconductor substrate (of the semiconductor substrate is thin). In this case, the bottom surface of the electrically conductive structure may be the bottom surface of the electrically conductive line. In this way, a connection from front side to back side may be implemented with low effort, since the number of necessary process steps may be kept low. Alternatively, a through substrate via may be connected to the electrically conductive line (e.g. if the semiconductor substrate is hick). For example, the through substrate via may extend from a bottom surface of the electrically conductive line to the backside of the semiconductor substrate. In this case, the bottom surface of the electrically conductive structure may be the bottom surface of the through substrate via.

For example, analogous to method 300, the plurality of transistors may be formed on a semiconductor wafer instead of on a semiconductor substrate. This way, a plurality of plurality of transistors can be formed with an eased manufacturing process. Further, the semiconductor wafer can be used to attach the plurality of plurality of transistors to a plurality of backside metallization layer stacks. For example, the plurality of backside metallization layer stacks may be formed on a carrier, e.g., a wafer, and thus the attachment may be performed by a wafer-to-wafer process, e.g., a wafer-to-wafer bonding process. This way, an alignment for attaching can be increased. The semiconductor wafer comprising the plurality of plurality of transistors and the carrier comprising the plurality of backside metallization layer stacks can be alignment more accurately compared to a semiconductor substrate and a backside metallization layer stack, because handling can be improved, e.g., a wafer-to-wafer bonding process is more accurate. Thus, a plurality of semiconductor dies can be formed in improved manufacturing process, which may increase a yield of the manufacturing process.

After attaching the semiconductor wafer to the carrier to form the plurality of semiconductor dies the carrier may be removed and the semiconductor waver may be diced to separate the plurality of semiconductor dies. The separated semiconductor dies can then be attached to a package substrate to provide a packed semiconductor die.

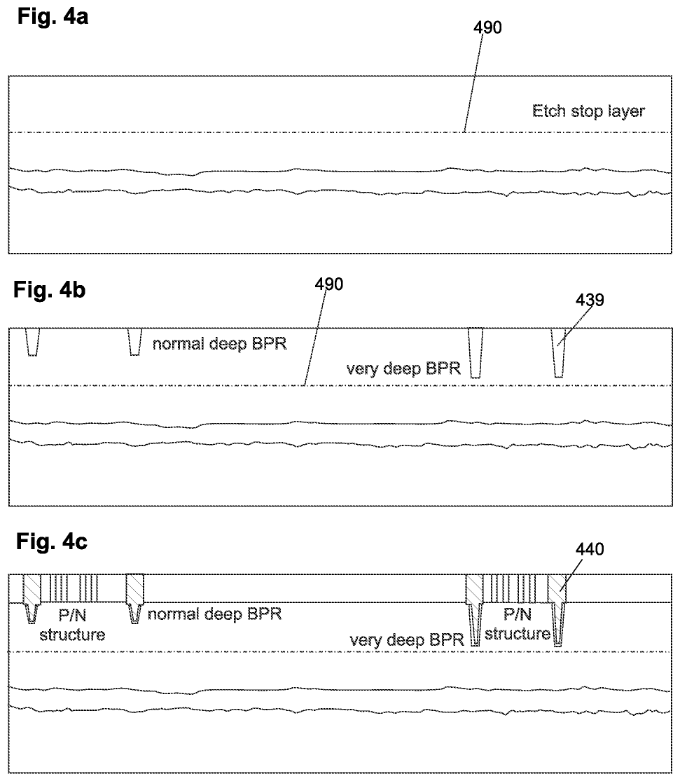

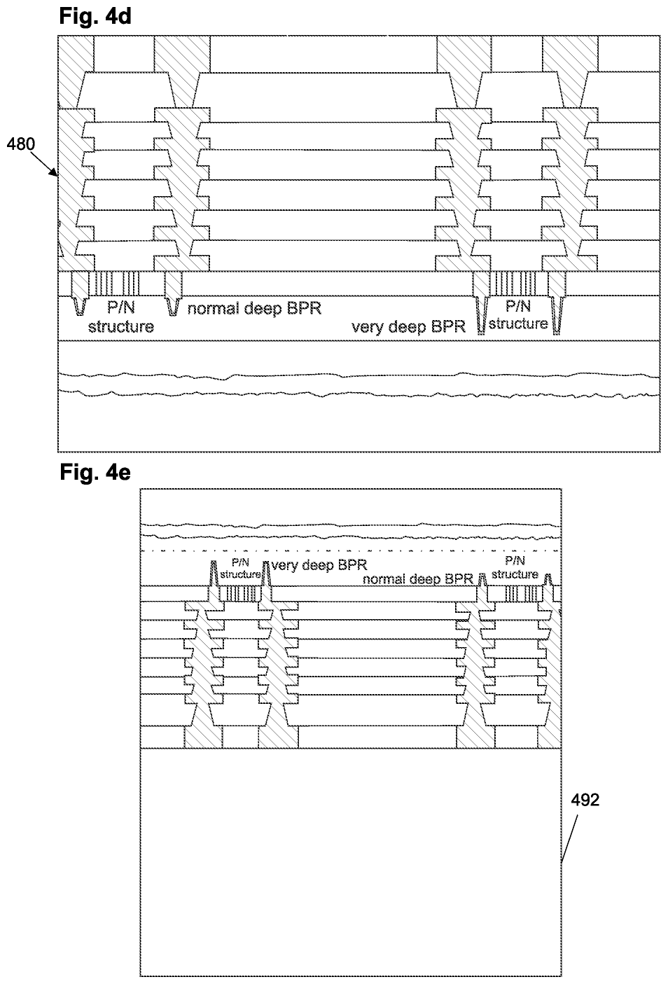

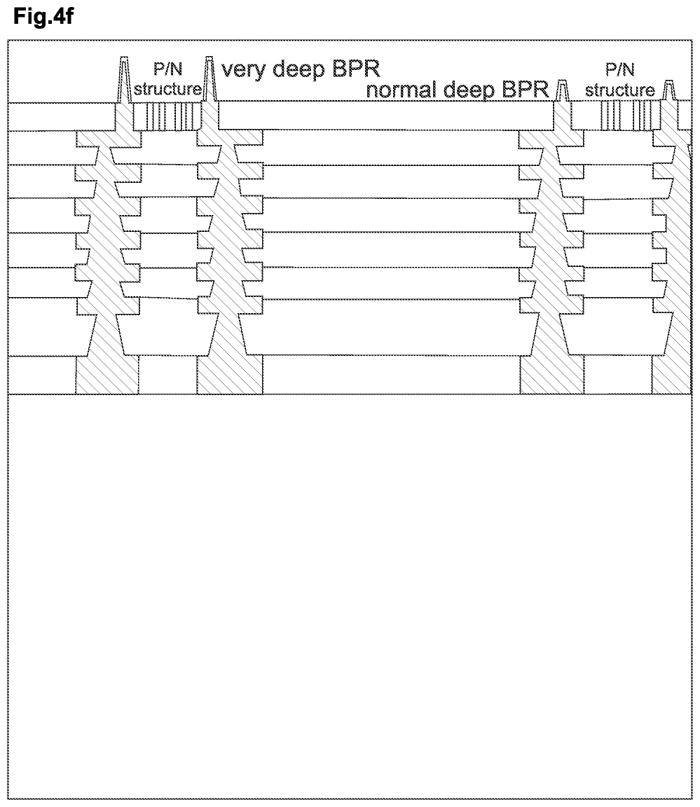

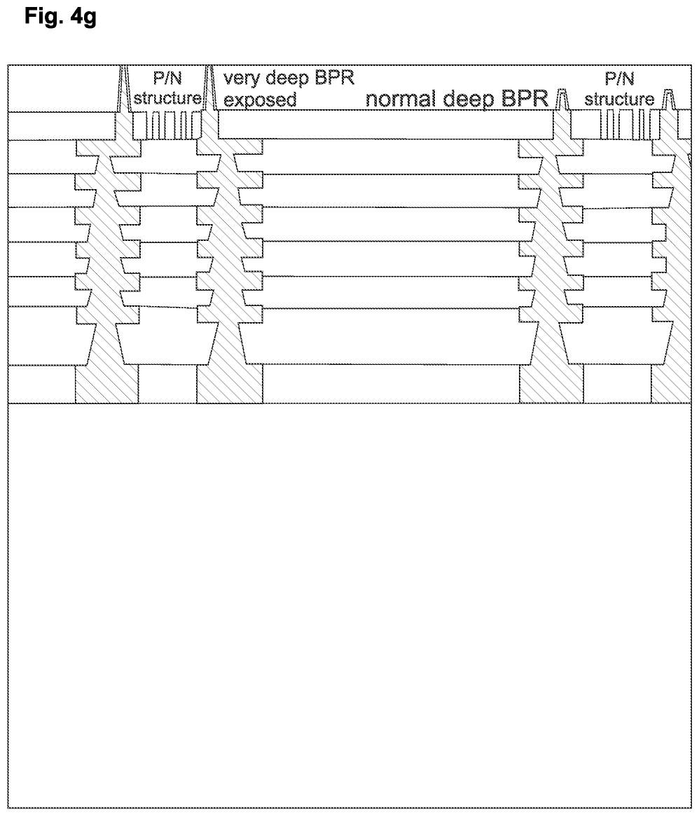

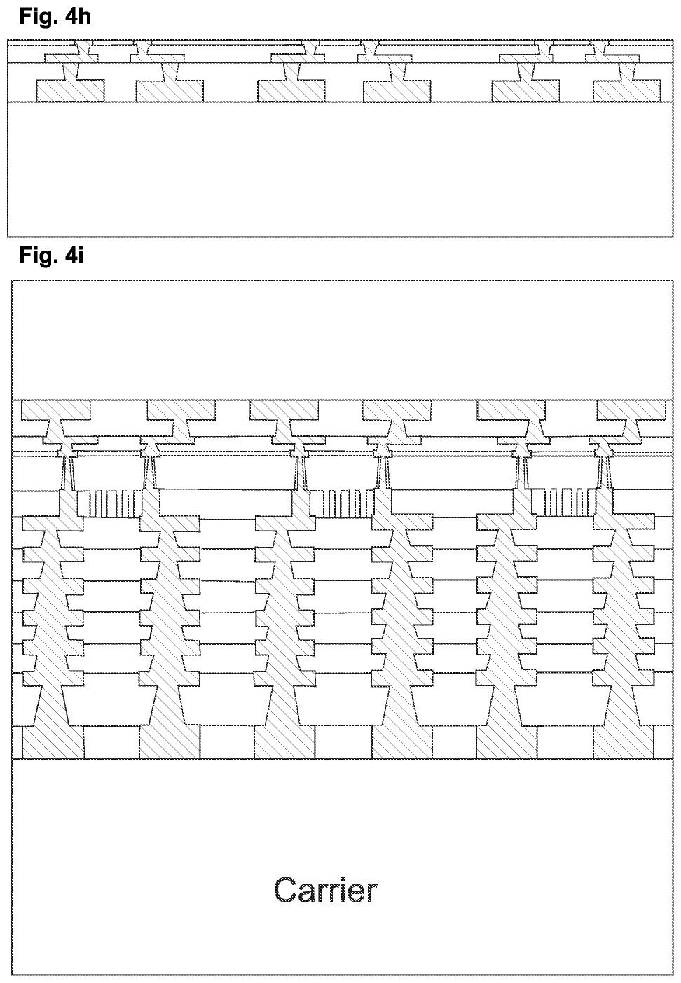

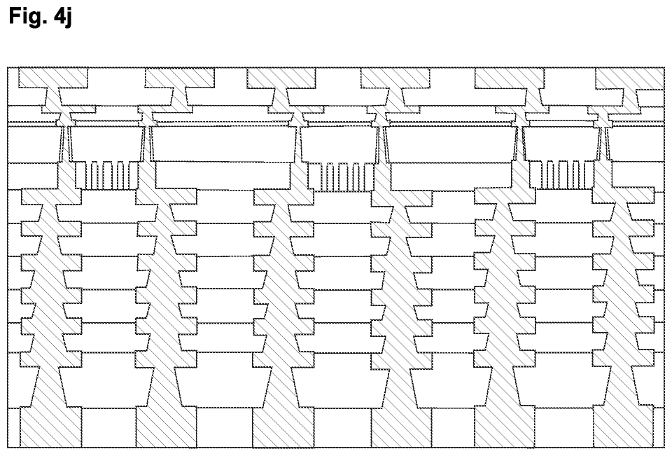

More details and aspects are mentioned in connection with the examples described above and/or below. The example shown in FIG. 3 may comprise one or more optional additional features corresponding to one or more aspects mentioned in connection with the proposed concept or one or more examples describe above (e.g., FIGS. 1-2) and/or below (e.g., FIGS. 4-6).

FIG. 4 shows an example of a method for forming a semiconductor die. The FIGS. 4a-4f show an example of a method for forming a semiconductor substrate for the semiconductor die. In an example, the method may comprise forming an etch stop layer inside the semiconductor substrate, The etch stop layer is located at a depth larger than a depth of the trench for the electrically conductive line. FIG. 4a shows a semiconductor substrate (e.g., a thick wafer) with an etch stop layer 490. The brighter area in the middle of the semiconductor substrate illustrates a break in the semiconductor substrate, to reflect that the semiconductor substrate has full thickness.

In an example, the method may further comprise forming the electrically conductive line comprising forming a trench into the semiconductor substrate from the front side of the semiconductor substrate and filling the trench with electrically conductive material of the electrically conductive line. Further, removing a part of the semiconductor substrate from the backside of the semiconductor substrate to uncover the bottom surface of the electrically conductive line may be comprised.

For a hybrid bonding connection to a bottom of the electrically conductive line each trench for forming the electrically conductive line need to be embedded deep in the Si-Bulk and stop right over the etch layer. The forming of the trench may comprise for example, forming a very deep trench 439 for an electrically conductive line, such like a deep buried power rail (BPR) may be formed. As can be seen in FIG. 4b a trench for a normal deep BPR may have a larger distance to the etch stop layer 490 as the very deep trench 439 for the very deep BPR. In an example, a distance between the etch stop layer and the trench 439 may be at most 100 nm, at most 70, at most 50 nm, at most 30 nm or at most 10 nm and/or at least 10 nm, at least 30 or at least 50 nm, which may be only achieved for the very deep BPR. When generating the very deep trench 439 for the very deep BPR (e.g., a via) a depth of the very deep trench 439 may be stopped right above the etch stop layer 490. Further, the very deep trench 439 may be isolated against the semiconductor substrate.

As can be seen in FIG. 4c the electrically conductive line 440 and the plurality of transistors may be formed after forming the trenches. After forming the very deep trench 439 the very deep trench may be filled (e.g., by any suitable conductive material) to form the electrically conductive line 440, e.g., the very deep BPR 440.

FIG. 4d shows the semiconductor substrate with the front wiring structure 480, which is attached to the front side of the semiconductor substrate. The front wiring structure 480 may be formed by FEOL and/or BEOL process(es).

FIG. 4e shows a flipped semiconductor substrate. A carrier system 492 may be attached to a front side of the front wiring structure (and thus at the side of the active side of the semiconductor substrate). The carrier system 492 may reduce warping during a removing of the backside of the semiconductor substrate. Further, the carrier system 492 may be used for following processes, such like alignment with the backside metallization layer stack, which may increase an alignment accuracy.

In an example, the method may further comprise removing a first part of the semiconductor substrate from the backside until the etch stop layer is reached. Removing the first part comprises at least one of mechanical etching, dry etching or wet etching. As can be seen in FIG. 4f, after a first removing process of the backside of the semiconductor substrate, the very deep BPR may be not yet uncovered. For example, the first removing process may be used to remove the backside of the semiconductor substrate to the etch stop layer. This may comprise/be performed by grinding down the backside of the semiconductor substrate till the etch stop layer (e.g., with mechanical and/or wet/dry etch processes).

In an example, the method may further comprise uncovering the bottom surface of the electrically conductive structure by removing a second part of the semiconductor substrate by at least one of chemical mechanical planarization or plasma etching. For example, removing the second part may comprise/be performed by a more accurate process as removing the first part, thus a processing time of the semiconductor substrate may be decreased, and an accuracy may be increased. A surface area of the very deep PBR may be uncovered after removing the second part, as can be seen in FIG. 4g. For example, the bottom surface of the electrically conductive line as described above (e.g., with respect to FIG. 1) may be the uncovered surface area of the very deep BPR.

FIG. 4h shows a cross-sectional view of the backside metallization layer stack before attaching it to the semiconductor substrate. The backside metallization layer stack may be a thick backside wafer with a backside metallization stack (e.g., the tapered vertical connection and the second portion of the wiring structure as described above) and the hybrid bond pads (e.g., the first portion of the wiring structure as described above).

For the backside metallization layer stack, including the (fine) hybrid bond pad, a dedicated substrate/wafer may be generated. In an example, the method may further comprise forming the backside metallization layer stack on a carrier. In an example, the carrier comprises or is made of at least one of stainless steel, glass or semiconductor material.

Starting on a such a carrier, e.g., a thick silicon wafer or a stiff carrier wafer (e.g. stainless steel or any other stiff material), first the thick copper layers may be formed, followed by a planarization process to get rid of topography. Finally, the hybrid bond pad may be generated with a dimension of at most 120 nm, or at most 100 nm, or at most 80 nm, or at most 60 nm with front end processes and within materials for annealing to the wafer-to-wafer interface (e.g. silicon carbon nitride, silicon oxide, polyimide, etc.) besides the hybrid bond pad.

Optionally, since the backside metallization layer stack is processed separately from the semiconductor device, partial other materials for electrical or thermal improvements/functionality of the backside metallization layer stack may be generated layer by layer, such like a functional wafer. This could be a special dielectric a magnetic material and/or a material for better thermal power dissipation.

In an example, forming the backside metallization layer stack may comprises forming a first portion of a wiring structure of the backside metallization layer stack in a first metallization layer of the backside metallization layer stack and forming a second portion of the wiring structure in a second metallization layer of the backside metallization layer stack. Further, the method may comprise forming a tapered vertical connection between the first portion of the wiring structure and the second portion of the wiring structure. The first metallization layer is closer to the semiconductor substrate than the second metallization layer and a width of the tapered vertical connection increases towards the first metallization layer. In an example, forming the tapered vertical connection comprises forming a tapered via in the backside metallization layer stack (see e.g., FIG. 4h).

As can be seen in FIG. 4i the semiconductor substrate and the backside metallization layer stack are attached to each other. For example, the first portion of the wiring structure, e.g., a hybrid bond pad, may be electrically connected with the bottom surface of the electrically conductive line, e.g., via hybrid bonding. In an example, attaching the backside metallization layer stack comprises or is done by a wafer bonding process. For example, the (preprocessed) backside metallization layer stack may be mounted with a wafer-to-wafer bonding process on the backside of the (functional) semiconductor substrate comprising the front side wiring layer stack.

In an example, the method may further comprises aligning the carrier to the semiconductor substrate for attaching the backside metallization layer stack to the semiconductor substrate so that the bottom surface of the electrically conductive structure is connected to a contact interface structure of the backside metallization layer stack. This way, a wafer-to-wafer bonding process may be comprised or done. Due to the very good accuracy of the wafer-to-wafer bonding process, the small uncovered bottom surface of the electrically conductive line with, e.g., at most 100 nm minimal lateral dimension (e.g., a side length), can be met with the first portion of the wiring structure (e.g., the hybrid bonding pad). Thus, the wafer-to-wafer bonding process may increase a yield of the manufacturing of the semiconductor die, since wafer-to-wafer bonding is a high precision bonding process. For example, a connection between the bottom surface of the electrically conductive line and the first portion of the wiring structure may be seamless due to the hybrid bonding interface. As the backside metallization layer stack itself may be formed on a thick carrier a handling may be improved, which may lead to generate a very smooth and flat surface for the wafer-to-wafer bonding process. For example, if required an additional carrier system could be used.

In an example, the bonding process comprises or is done by a hybrid bonding process. Hybrid bonding extends direct bonding with embedded metal pads in the bond interface (e.g., the first portion of the wiring structure), allowing for face-to-face connection of wafers. This way, in comparison to non-hybrid bonding a precision of the bonding process may be increased.

Hybrid bonding is a direct bonding process using, e.g., a plasma treatment of the substrates prior to bonding whereas the wafer surface consists out of dielectric and metal interconnects on the same surface plane, e.g., the front side of the backside metallization layer stack. Room temperature contacting of the wafers (pre-bonding) and thermal annealing for strengthening the bond may be comprised during a hybrid bonding process. In an example, a temperature of the backside of the semiconductor substrate may be at least 25° C., at least 50° C. or at least 75° C. and/or at most 150° C., at most 125° C. or at most 100° C. during attaching the backside metallization layer stack. In an example, the backside of the semiconductor substrate may be pressed to the backside of the semiconductor substrate with a pressure of at least 2 bar, at least 1 bar or at least 0.5 bar (normal atm).

FIG. 4j shows the finished semiconductor die process to generate a semiconductor die comprising an electrical connection to the electrically conductive line of the semiconductor substrate on the backside of the semiconductor die via the wiring structure of the backside metallization layer stack. In an example, the method may further comprise removing the carrier from the backside metallization layer stack after attaching the backside metallization layer stack to the backside of the semiconductor substrate. Further, the carrier of the semiconductor substrate may be removed.

To remove the respective carrier of the semiconductor substrate and the backside metallization layer stack a grinding process may be comprised or done. For example, grinding of the (thick) carrier of the backside metallization layer stack e.g. the thick silicon wafer (or any other material acted like a carrier and revel it) to uncover the second portion of the wiring structure, e.g., a backside metallization, may be done. The same may be done on the other side of the semiconductor die with the carrier of the semiconductor substrate to uncover, e.g., C4 pads of the (functional) front side wiring layer stack.

Concluding, with the method described with reference to FIG. 4 complicated tiny TSV processes can be omitted by utilizing a hybrid pond pad to electrically connect the electrically conductive line of the semiconductor substrate.

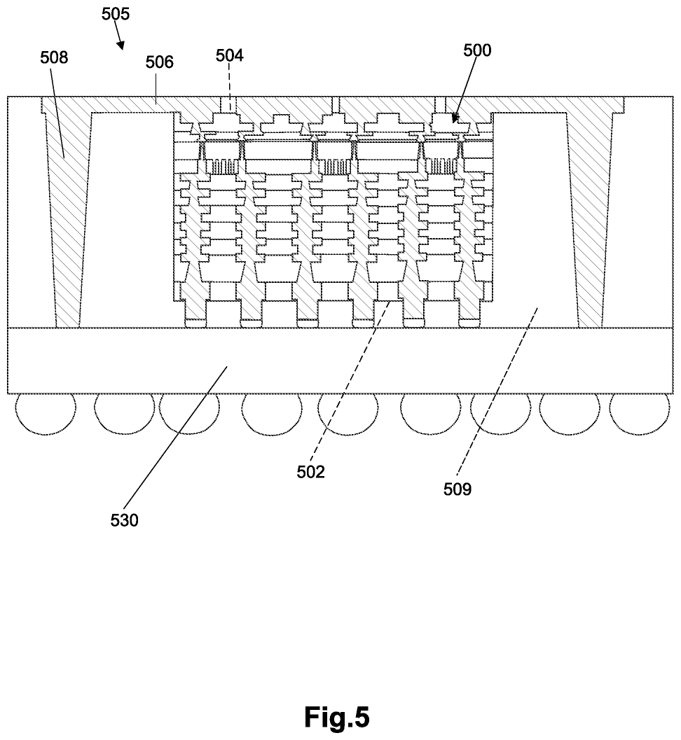

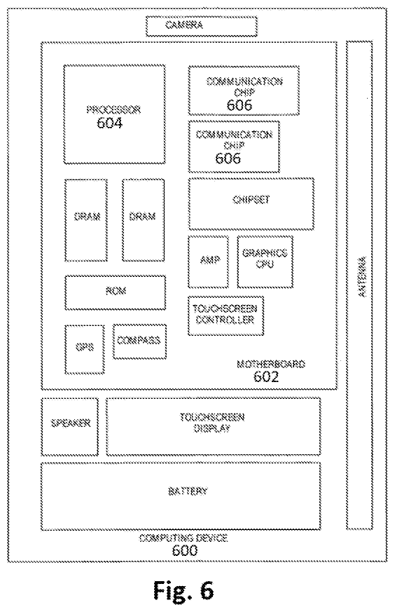

More details and aspects are mentioned in connection with the examples described above and/or below. The example shown in FIG. 4 may comprise one or more optional additional features corresponding to one or more aspects mentioned in connection with the proposed concept or one or more examples describe above (e.g., FIGS. 1-3) and/or below (e.g., FIGS. 5-6).

FIG. 5 shows a cross-sectional view of a semiconductor device 505. In an example, the semiconductor device 505 comprises a semiconductor die 500 as described above (e.g., with respect to FIG. 1, FIG. 2 and FIGS. 4a-4j) and a package substrate 530 attached to a front side of the semiconductor die 500. The semiconductor die 500 comprises a semiconductor substrate comprising a front side wiring layer stack and a backside metallization layer stack.

For example, with connection technics (e.g. a Through Mold Via and a RDL process), the backside metallization layer stack, e.g. a backside metallization, can be connected to generate a functional package, e.g., following assembly processes may be bumping of the C4 pads of the (functional) front side wiring layer stack and attaching the semiconductor die 500 to a packing substrate 530.

In an example, a redistribution layer 506 may be formed on a backside of the semiconductor die 504. The redistribution layer 506 may be electrically connected to a second contact interface structure of the backside metallization layer stack. In an example, the second portion of the wiring structure may be the second contact interface structure connected to the backside metallization layer stack.

In an example, an interconnect structure 508 may be arranged laterally besides the semiconductor die 500 and extending from the redistribution layer 506 to the package substrate 530. This way, a connection between the backside of the semiconductor die 504 and the front side of the package substrate can be achieved.

In an example, the semiconductor device 505 may further comprise a mold compound 509 embedding the semiconductor die 500 and the interconnect structure 508. In this case, the interconnect structure 508 may be a through mold via.

A semiconductor device 505 described above or below may be a semiconductor package comprising a semiconductor die 500. The semiconductor device 505 may be a processor (e.g. CPU, GPU or DSP), a memory or any other integrated circuit.

More details and aspects are mentioned in connection with the examples described above and/or below. The example shown in FIG. 5 may comprise one or more optional additional features corresponding to one or more aspects mentioned in connection with the proposed concept or one or more examples describe above (e.g., FIGS. 1-4) and/or below (e.g., FIG. 6).

FIG. 6 illustrates a computing device 600. The computing device 600 houses a board 602. The board 602 may include a number of components, including but not limited to a processor 604 and at least one communication chip 606. A semiconductor device as described above (e.g., with respect to FIG. 5) may be the processor 604 as shown in FIG. 6. For example, the processor 604 may comprise the semiconductor die as described with reference to FIG. 1.

The processor 604 is physically and electrically coupled to the board 602. In some embodiments the at least one communication chip 606 is also physically and electrically coupled to the board 602. In further embodiments, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others. The processor 604 of the computing device 600 includes an integrated circuit die packaged within the processor 604. In some embodiments, the integrated circuit die of the processor includes one or more devices that are assembled in an ePLB or eWLB based POP package that that includes a mold layer directly contacting a substrate, in accordance with embodiments. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another embodiment, the integrated circuit die of the communication chip includes one or more devices that are assembled in an ePLB or eWLB based P0P package that that includes a mold layer directly contacting a substrate, in accordance with embodiments.

More details and aspects are mentioned in connection with the examples described above. The example shown in FIG. 6 may comprise one or more optional additional features corresponding to one or more aspects mentioned in connection with the proposed concept or one or more examples described above (e.g., FIGS. 1-5).

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

An example (e.g., example 1) relates to a semiconductor die, comprising a plurality of transistors arranged at a front side of a semiconductor substrate, an electrically conductive structure, wherein a top surface of the electrically conductive structure is contacted at the front side of the semiconductor substrate and a bottom surface of the electrically conductive structure is contacted at a backside of the semiconductor substrate and a backside metallization layer stack attached to the backside of the semiconductor substrate, wherein a first portion of a wiring structure of the backside metallization layer stack is formed in a first metallization layer of the backside metallization layer stack, a second portion of the wiring structure is formed in a second metallization layer of the backside metallization layer stack, and a tapered vertical connection is formed between the first portion of the wiring structure and the second portion of the wiring structure, wherein the first metallization layer is closer to the semiconductor substrate than the second metallization layer, wherein a width of the tapered vertical connection increases towards the first metallization layer.

Another example (e.g., example 2) relates to a previously described example (e.g., example 1) wherein the first portion of the wiring structure is a contact interface structure connected to the bottom surface of the electrically conductive structure.

Another example (e.g., example 3) relates to a previously described example (e.g., the example 2) wherein the backside metallization layer stack further comprises a bonding surface layer arranged besides the contact interface structure comprising at least one of silicon carbon nitride, silicon oxide or polyimide.

Another example (e.g., example 4) relates to a previously described example (e.g., one of the examples 2-3) wherein a length of the contact interface structure is at most 100 nm.

Another example (e.g., example 5) relates to a previously described example (e.g., one of the examples 1-4) wherein a minimal lateral dimension of the bottom surface of the electrically conductive structure is at most 100 nm.

Another example (e.g., example 6) relates to a previously described example (e.g., one of the examples 1-5) wherein a thickness of the first metallization layer is at most 100 nm.

Another example (e.g., example 7) relates to a previously described example (e.g., one of the examples 1-6) wherein a thickness of the semiconductor substrate is at most 100 nm.

Another example (e.g., example 8) relates to a previously described example (e.g., one of the examples 1-7) wherein the plurality of transistors comprises at least one of a fin field-effect transistor, a nanowire transistor, a ribbon transistor or a gate all around transistor.

Another example (e.g., example 9) relates to a previously described example (e.g., one of the examples 1-8) wherein the electrically conductive structure is electrically insulated from the semiconductor substrate.

Another example (e.g., example 10) relates to a previously described example (e.g., one of the examples 1-9) a layer of the backside metallization layer stack comprises a dielectric material of a capacitor, e.g., Silicon Oxide or Silicon Nitride compositions.

Another example (e.g., example 11) relates to a previously described example (e.g., one of the examples 1-10) wherein a layer of the backside metallization layer stack comprises a magnetic material of an inductor , e.g., a Ferro Oxide (iron oxide) or Ferro Platinum (iron platinum) compositions.

Another example (e.g., example 12) relates to a previously described example (e.g., one of the examples 1-11) a layer of the backside metallization layer stack comprises a material with a thermal conductivity of at least 1 W/mK.

Another example (e.g., example 13) relates to a previously described example (e.g., one of the examples 1-12) wherein the backside metallization layer stack comprises a circuit element electrically connected to the electrically conductive structure.

Another example (e.g., example 14) relates to a previously described example (e.g., the example 13) further comprising circuitry comprising at least one transistor of the plurality of transistors, wherein the circuit element is electrically connected to the transistor of the circuitry via the electrically conductive structure.

Another example (e.g., example 15) relates to a previously described example (e.g., one of the examples 1-14) further comprising a front side wiring layer stack formed on the front side of the semiconductor substrate, wherein the front side wiring layer stack comprises a front side wiring structure electrically connected to the wiring structure of the backside metallization layer stack.

An example (e.g., example 16) relates to a semiconductor device, comprising a semiconductor die as describe above (e.g., one of the examples 1 -15) and a package substrate attached to a front side of the semiconductor die.

Another example (e.g., example 17) relates to a previously described example (e.g., the example 16) further comprising a redistribution layer formed on a backside of the semiconductor die, wherein the redistribution layer is electrically connected to a second contact interface structure of the backside metallization layer stack.

Another example (e.g., example 18) relates to a previously described example (e.g., the example 17) wherein the second portion of the wiring structure is the second contact interface structure connected to the backside metallization layer stack.

Another example (e.g., example 19) relates to a previously described example (e.g., one of the examples 17-18) further comprising an interconnect structure arranged laterally beside the semiconductor die and extending from the redistribution layer to the package substrate.

Another example (e.g., example 20) relates to a previously described example (e.g., the example 19) further comprising a mold compound embedding the semiconductor die and the interconnect structure.

An example (e.g., example 21) relates to a method for forming a semiconductor device, comprising forming a plurality of transistors arranged at a front side of a semiconductor substrate and an electrically conductive structure, wherein a top surface of the electrically conductive structure is contacted at the front side of the semiconductor substrate and a bottom surface of the electrically conductive structure is uncovered at a backside of the semiconductor substrate, forming a backside metallization layer stack and attaching the backside metallization layer stack to the backside of the semiconductor substrate.

Another example (e.g., example 22) relates to a previously described example (e.g., example 21) wherein forming the backside metallization layer stack comprises forming a first portion of a wiring structure of the backside metallization layer stack in a first metallization layer of the backside metallization layer stack, forming a second portion of the wiring structure in a second metallization layer of the backside metallization layer stack and forming a tapered vertical connection is between the first portion of the wiring structure and the second portion of the wiring structure, wherein the first metallization layer is closer to the semiconductor substrate than the second metallization layer and wherein a width of the tapered vertical connection increases towards the first metallization layer.

Another example (e.g., example 23) relates to a previously described example (e.g., the example 22) wherein forming the tapered vertical connection comprises forming a tapered via in the backside metallization layer stack.

Another example (e.g., example 24) relates to a previously described example (e.g., one of the examples 21-23) wherein attaching the backside metallization layer stack comprises a wafer bonding process.

Another example (e.g., example 25) relates to a previously described example (e.g., the example 24) wherein the bonding process comprises a hybrid bonding process.

Another example (e.g., example 26) relates to a previously described example (e.g., one of the examples 21-25) wherein a temperature of the backside of the semiconductor substrate is at least 25° C. during attaching the backside metallization layer stack.

Another example (e.g., example 27) relates to a previously described example (e.g., one of the examples 21-26) wherein the backside of the semiconductor substrate is pressed to the backside of the semiconductor substrate with a pressure of at least 1 bar.

Another example (e.g., example 28) relates to a previously described example (e.g., one of the examples 21-27) further comprising forming the backside metallization stack layer on a carrier.

Another example (e.g., example 29) relates to a previously described example (e.g., the example 28) wherein the carrier comprises at least one of stainless steel, glass or semiconductor material.

Another example (e.g., example 30) relates to a previously described example (e.g., one of the examples 28-29) further comprising aligning the carrier to the semiconductor substrate for attaching the backside metallization layer stack to the semiconductor substrate so that the bottom surface of the electrically conductive structure is connected to a contact interface structure of the backside metallization layer stack.

Another example (e.g., example 31) relates to a previously described example (e.g., one of the examples 28-30) further comprising removing the carrier from the backside metallization layer stack after attaching the backside metallization layer stack to the backside of the semi conductor substrate.

Another example (e.g., example 32) relates to a previously described example (e.g., one of the examples 21-31) wherein forming the electrically conductive structure comprises forming a trench into the semiconductor substrate from the front side of the semiconductor substrate, filling the trench with electrically conductive material of the electrically conductive structure and removing a part of the semiconductor substrate from the backside of the semiconductor substrate to uncover the bottom surface of the electrically conductive structure.

Another example (e.g., example 33) relates to a previously described example (e.g., the example 32) further comprising forming an etch stop layer inside the semiconductor substrate, wherein the etch stop layer is located at a depth larger than a depth of the trench for the electrically conductive structure.

Another example (e.g., example 34) relates to a previously described example (e.g., the example 33) wherein a distance between the etch stop layer and the trench is at most 50 nm.

Another example (e.g., example 35) relates to a previously described example (e.g., one of the examples 33-34) further comprising removing a first part of the semiconductor substrate from the backside until the etch stop layer is reached, wherein removing the first part comprises at least one of mechanical etching, dry etching or wet etching.

Another example (e.g., example 36) relates to a previously described example (e.g., the example 35) further comprising uncovering the bottom surface of the electrically conductive structure by removing a second part of the semiconductor substrate by at least one of chemical mechanical planarization or plasma etching.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A semiconductor die, comprising:
a plurality of transistors arranged at a front side of a semiconductor substrate;
an electrically conductive structure, wherein a top surface of the electrically conductive structure is contacted at the front side of the semiconductor substrate and a bottom surface of the electrically conductive structure is contacted at a backside of the semiconductor substrate; and
a backside metallization layer stack attached to the backside of the semiconductor substrate, wherein a first portion of a wiring structure of the backside metallization layer stack is formed in a first metallization layer of the backside metallization layer stack, a second portion of the wiring structure is formed in a second metallization layer of the backside metallization layer stack, and a tapered vertical connection is formed between the first portion of the wiring structure and the second portion of the wiring structure, wherein the first metallization layer is closer to the semiconductor substrate than the second metallization layer, wherein a width of the tapered vertical connection increases towards the first metallization layer.

2. The semiconductor die according to claim 1, wherein
the first portion of the wiring structure is a contact interface structure connected to the bottom surface of the electrically conductive structure.

3. The semiconductor die according to claim 2, wherein
the backside metallization layer stack further comprises a bonding surface layer arranged besides the contact interface structure comprising at least one of silicon carbon nitride, silicon oxide or polyimide.

4. The semiconductor die according to claim 2, wherein
a length of the contact interface structure is at most 100 nm.

5. The semiconductor die according to claim 1, wherein
a minimal lateral dimension of the bottom surface of the electrically conductive structure is at most 100 nm.

6. The semiconductor die according to claim 1, wherein
the plurality of transistors comprises at least one of a fin field-effect transistor, a nanowire transistor, a ribbon transistor or a gate all around transistor.

7. The semiconductor die according to claim 1, wherein
the electrically conductive structure is electrically insulated from the semiconductor substrate.

8. The semiconductor die according to claim 1, wherein
a layer of the backside metallization layer stack comprises a dielectric material of a capacitor.

9. The semiconductor die according to claim 1, wherein
a layer of the backside metallization layer stack comprises a magnetic material of an inductor.

10. The semiconductor die according to claim 1, wherein
the backside metallization layer stack comprises a circuit element electrically connected to the electrically conductive structure.

11. The semiconductor die according to claim 10, further comprising
circuitry comprising at least one transistor of the plurality of transistors, wherein the circuit element is electrically connected to the transistor of the circuitry via the electrically conductive structure.

12. The semiconductor die according to claim 1, further comprising
a front side wiring layer stack formed on the front side of the semiconductor substrate, wherein the front side wiring layer stack comprises a front side wiring structure electrically connected to the wiring structure of the backside metallization layer stack.

13. A semiconductor device, comprising:
a semiconductor die according to claim 1; and
a package substrate attached to a front side of the semiconductor die.

14. The semiconductor device according to claim 13, further comprising
a redistribution layer formed on a backside of the semiconductor die, wherein the redistribution layer is electrically connected to a second contact interface structure of the backside metallization layer stack.

15. The semiconductor device according to claim 14, wherein
the second portion of the wiring structure is the second contact interface structure connected to the backside metallization layer stack.

16. The semiconductor device according to claim 14, further comprising
an interconnect structure arranged laterally beside the semiconductor die and extending from the redistribution layer to the package substrate.

17. The semiconductor device according to claim 16, further comprising
a mold compound embedding the semiconductor die and the interconnect structure.

18. A method for forming a semiconductor device, comprising:
forming a plurality of transistors arranged at a front side of a semiconductor substrate and an electrically conductive structure, wherein a top surface of the electrically conductive structure is contacted at the front side of the semiconductor substrate and a bottom surface of the electrically conductive structure is uncovered at a backside of the semiconductor substrate;
forming a backside metallization layer stack; and
attaching the backside metallization layer stack to the backside of the semiconductor substrate.

19. The method according to claim 18, wherein
forming the backside metallization layer stack comprises:
forming a first portion of a wiring structure of the backside metallization layer stack in a first metallization layer of the backside metallization layer stack;
forming a second portion of the wiring structure in a second metallization layer of the backside metallization layer stack; and
forming a tapered vertical connection is between the first portion of the wiring structure and the second portion of the wiring structure, wherein the first metallization layer is closer to
the semiconductor substrate than the second metallization layer and wherein a width of the tapered vertical connection increases towards the first metallization layer.

20. The method according to claim 19, wherein
forming the tapered vertical connection comprises forming a tapered via in the backside metallization layer stack.
